(19) United States
(12) Patent Application Publication
(10) Pub. No.: US 2019/0148911 A1
(43) Pub. Date: May 16, 2019

(54) TECHNIQUES FOR PROVIDING CURVED FACET SEMICONDUCTOR LASERS

(71) Applicant: MACOM Technology Solutions Holdings, Inc., Lowell, MA (US)

(72) Inventors: Youxi LIN, Ithaca, NY (US); Wolfgang PARZ, Ithaca, NY (US); Nathan BICKEL, Ithaca, NY (US); Cristian STAGARESCU, Ithaca, NY (US)

(73) Assignee: MACOM Technology Solutions Holdings, Inc., Lowell, MA (US)

(21) Appl. No.: 16/192,396

(22) Filed: Nov. 15, 2018

Related U.S. Application Data
(60) Provisional application No. 62/586,505, filed on Nov. 15, 2017.

(51) Int. Cl. H01S 5/10; H01S 5/028

(52) U.S. Cl. CPC H01S 5/101; H01S 5/1082; H01S 5/0287

(57) ABSTRACT

Techniques for providing curved facet semiconductor lasers. are disclosed. In one particular embodiment, the techniques may be realized as a semiconductor laser, comprising a waveguide, wherein the waveguide includes a facet formed at an edge of the semiconductor laser, and the facet has a curvature.

### CROSS-REFERENCE TO RELATED APPLICATIONS

This patent application claims priority to U.S. Provisional Patent Application No. 62/586,505 filed on Nov. 15, 2017, the contents of which are hereby incorporated by reference herein in their entirety.

### FIELD OF THE DISCLOSURE

The present disclosure relates generally to semiconductors, and more particularly, to techniques for providing curved facet semiconductor lasers.

### BACKGROUND OF THE DISCLOSURE

Semiconductor lasers are typically fabricated on a wafer by growing an appropriate layered semiconductor material on a substrate through Metalorganic Chemical Vapor Deposition (MOCVD) or Molecular Beam Epitaxy (MBE) to form an epitaxial structure having an active layer parallel to the substrate surface. The wafer may then be processed with a variety of semiconductor processing tools to produce a laser optical cavity incorporating the active layer and incorporating metallic contacts attached to the semiconductor material.

Laser mirror facets typically are formed at the ends of the laser cavity by cleaving the semiconductor material along its crystalline structure to define edges, or ends, of the laser optical cavity so that when a bias voltage is applied across the contacts, resulting current flow through the active layer causes photons to be emitted out of the faceted edges of the active layer in a direction perpendicular to the current flow. Since the semiconductor material is cleaved to form the laser facets, the locations and orientations of the facets are limited. Furthermore, once the wafer has been cleaved, the lasers are typically in small pieces so that conventional lithographical techniques cannot readily be used to further process the lasers.

The photons emitted from the faceted edges may be emitted with different vertical and horizontal far field patterns, which may cause an asymmetry between the vertical and horizontal far fields. This asymmetry can be detrimental to laser operation. For example, when a semiconductor laser is coupled to a transmission medium, such as an optical fiber, the transmission medium may capture only a limited percentage of photons due to the asymmetrical far field patterns. Thus, coupling loss may be increased. Complex external aspherical optical elements, such as lenses, may be required to correct the asymmetry and ensure a reduction of coupling loss. These optical elements, however, are often costly, and may increase the overall cost of semiconductor laser fabrication and use.

In view of the foregoing, it may be understood that there may be significant problems and shortcomings associated with current semiconductor laser fabrication techniques.

### SUMMARY OF THE DISCLOSURE

Techniques for providing curved facet semiconductor lasers are disclosed. In one particular embodiment, the techniques may be realized as a semiconductor laser, comprising a waveguide, wherein the waveguide includes a facet formed at an edge of the semiconductor laser, and the facet has a curvature.

In accordance with other aspects of this particular embodiment, the facet curvature may be based on a width of the facet.

In accordance with other aspects of this particular embodiment, the facet curvature may be based on a depth of the facet.

In accordance with further aspects of this particular embodiment, the depth of the facet may be measured from the edge of the semiconductor laser to a minimum depth of the facet.

In accordance with further aspects of this particular embodiment, the minimum depth of the facet may be located in a central region of the facet.

In accordance with other aspects of this particular embodiment, the facet curvature may be based on a radius.

In accordance with other aspects of this particular embodiment, the facet is configured to emit light, and the facet curvature causes the emitted light to have a reduced amount of far field asymmetry relative to light emitted without the facet curvature.

In accordance with other aspects of this particular embodiment, the facet curvature may be formed by etching.

In accordance with further aspects of this particular embodiment, the etching may be chemically assisted ion beam etching.

In accordance with other aspects of this particular embodiment, the facet curvature may be concave relative to the edge of the semiconductor laser.

In accordance with other aspects of this particular embodiment, the facet curvature may be convex relative to the edge of the semiconductor laser.

In accordance with other aspects of this particular embodiment, the facet curvature may satisfy the following equation: (w/2)²+(r−l)²=r² where w is a width of the facet, r is a radius, and l is a depth of the facet.

In another particular embodiment, the technique may be realized as a method of semiconductor laser fabrication, comprising etching a facet at an edge formed by a waveguide, wherein the facet has a curvature.

In accordance with other aspects of this particular embodiment, the facet curvature may be based on a width of the facet.

In accordance with other aspects of this particular embodiment, the facet curvature may be based on a depth of the facet.

In accordance with other aspects of this particular embodiment, the facet curvature may be based on a radius.

In accordance with other aspects of this particular embodiment, the facet curvature may be formed by chemically assisted ion beam etching.

In accordance with other aspects of this particular embodiment, the facet curvature may be concave relative to the edge of the semiconductor laser.

In accordance with other aspects of this particular embodiment, the facet curvature may be convex relative to the edge of the semiconductor laser.

In another particular embodiment, a semiconductor laser may comprise a waveguide and a substrate attached to the waveguide, wherein the waveguide and the substrate include a facet formed at an edge of the semiconductor laser, and the facet has a curvature.

In accordance with other aspects of this particular embodiment, the facet curvature may be concave relative to the edge of the semiconductor laser.

In accordance with other aspects of this particular embodiment, the facet curvature may be convex relative to the edge of the semiconductor laser.

In accordance with other aspects of this particular embodiment, the facet curvature may satisfy the following equation: (w/2)²+(r−l)²=r², where w is a width of the facet, r is a radius, and l is a depth of the facet.

The present disclosure will now be described in more detail with reference to particular embodiments thereof as shown in the accompanying drawings. While the present disclosure is described below with reference to particular embodiments, it should be understood that the present disclosure is not limited thereto. Those of ordinary skill in the art having access to the teachings herein will recognize additional implementations, modifications, and embodiments, as well as other fields of use, which are within the scope of the present disclosure as described herein, and with respect to which the present disclosure may be of significant utility.

### BRIEF DESCRIPTION OF THE DRAWINGS

In order to facilitate a fuller understanding of the present disclosure, reference is now made to the accompanying drawings, in which like elements are referenced with like numerals. These drawings should not be construed as limiting the present disclosure, but are intended to be illustrative only.

FIG. 1A shows a cross sectional view of a semiconductor laser in accordance with an embodiment of the present disclosure.

FIG. 1B shows a top view of the semiconductor laser in accordance with an embodiment of the present disclosure.

FIG. 1C shows a three-dimensional cross section view of the semiconductor laser in accordance with an embodiment of the present disclosure.

FIG. 2A shows a simulated heat map of light emitted from the semiconductor laser in accordance with an embodiment of the present disclosure.

FIG. 2B shows a graph, which displays the data of the heat map of light emitted from the semiconductor laser in a graphical format in accordance with an embodiment of the present disclosure.

FIG. 3A shows a top view of a semiconductor laser with a concave curved facet in accordance with an embodiment of the present disclosure.

FIG. 3B shows three-dimensional cross section view of the semiconductor laser with a curved facet in accordance with an embodiment of the present disclosure.

FIG. 3C shows a close-up view of the curved facet of the semiconductor laser with the curved facet.

FIG. 4A shows a simulated heat map of light emitted from the semiconductor laser with a curved facet in accordance with an embodiment of the present disclosure.

FIG. 4B shows a graph, which displays the data of the heat map of light emitted from the semiconductor laser with a curved facet in a graphical format in accordance with an embodiment of the present disclosure.

FIGS. 4C and 4D show an example of how anti-reflection properties may be improved depending on laser facet in accordance with an embodiment of the present disclosure.

FIG. 5A shows a graph, which displays different spans of the horizontal angle of the horizontal far field component of light emitted from the semiconductor laser with a curved facet in accordance with an embodiment of the present disclosure.

FIG. 5B shows a zoomed-in portion of the graph shown in FIG. 5A.

FIGS. 6A-6C show experimental results from testing a reference semiconductor laser and semiconductor lasers with varying edge facet curvatures in accordance with an embodiment of the present disclosure.

FIG. 7 shows a graph, which reflects the output light power in milliwatts (mW) of semiconductor lasers versus current in milliamps (mA) in accordance with an embodiment of the present disclosure.

FIG. 8 shows a top view of a semiconductor laser with a convex curved facet in accordance with an embodiment of the present disclosure.

### DETAILED DESCRIPTION OF EMBODIMENTS

The present disclosure and the related advantages are described and highlighted in the following description and accompanying figures which are not necessarily drawn to scale. Detailed descriptions of some structure and processing techniques are omitted so as to not unnecessarily obscure the present disclosure.

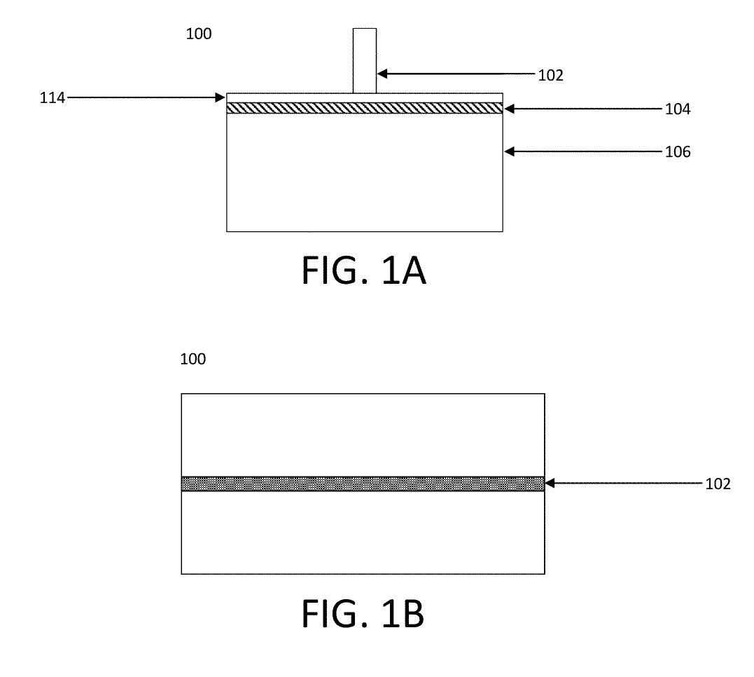

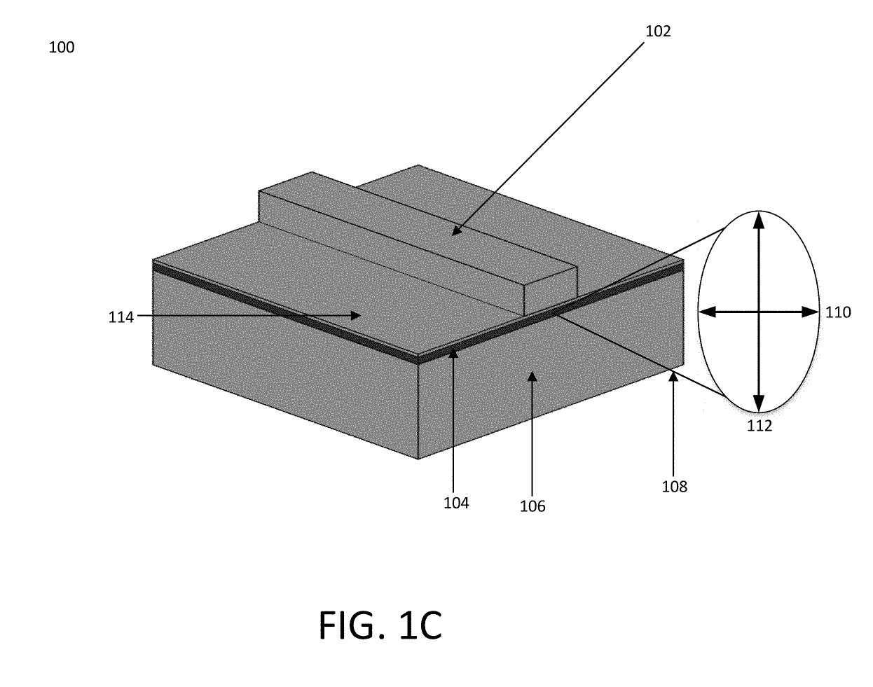

FIG. 1A shows a cross sectional view of a semiconductor laser 100 in accordance with an embodiment of the present disclosure. Semiconductor laser 100 may be a ridge diode laser that includes ridge 102. Semiconductor laser 100 may also include waveguide 104 and substrate 106. For example, substrate 106 may be an Indium phosphide (InP) based material, and waveguide 104 may be an AlGaInAs based material. Ridge 102 may be an InP based material, for example. A spacer layer 114 may positioned between ridge 102 and waveguide 104. Spacer layer 114 may be made from the same material(s) as ridge 102. Alternatively, spacer layer 114 may be part of ridge 102, and may be a residual layer that together with ridge 102 is a single structure.

FIG. 1B shows a top view of semiconductor laser 100 in accordance with an embodiment of the present disclosure. As shown in FIG. 1B, ridge 102 extends from one edge of semiconductor laser 100 to an opposite edge of semiconductor laser 100.

FIG. 1C shows a three-dimensional cross section view of semiconductor laser 100 in accordance with an embodiment of the present disclosure. As shown in FIG. 1C, light 108 is emitted from waveguide 104 at a facet of semiconductor laser 100. Light 108 has a horizontal far field component 110 and a vertical far field component 112. Due to asymmetric geometry of the facet where light exits waveguide 104, light 108 may diverge in different directions and/or at different angles, and components 110 and 112 may have different dimensions. Indeed, a vertical far field may diverge faster than a horizontal far field, and the full width half maximum of a horizontal far field may be much narrower compared to the vertical far field. Therefore, as shown by FIG. 1C, the size of vertical far field component 112 may be larger than the size of horizontal far field component 110. This difference in the dimensions of components 110 and 112 may cause light 108 to have an asymmetric far field pattern. Upon coupling light 108 to a transmission medium, such as an optical fiber, the asymmetric far field pattern may cause an astigmatism because the virtual focal points of horizontal far field component 110 and vertical far field component 112 may be at different locations. This astigmatism may reduce coupling efficiency to the transmission medium, and coupling loss may be increased. Complex aspherical optical elements, such as lenses, may be required to correct the asymmetry and ensure a reduction of coupling loss. These optical elements, however, may be costly, and may increase the cost of semiconductor laser fabrication and use.

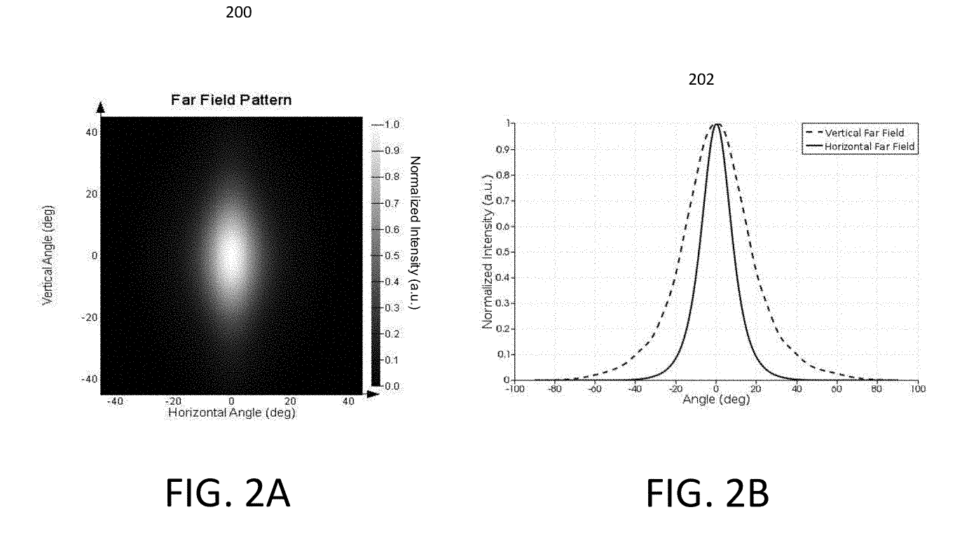

FIG. 2A shows a simulated heat map 200 of light 108 in accordance with an embodiment of the present disclosure. Heat map 200 indicates the vertical angle of vertical far field component 112 on its left-hand y-axis. The horizontal angle of horizontal far field component 110 is included on the x-axis of heat map 200. The normalized intensity of light 108 in arbitrary units (a.u.) is included on the right-hand y-axis of heat map 200. As shown by heat map 200, compared to the horizontal angle of horizontal far field component 110, the vertical angle of vertical far field component 112 spans a larger range of angles where normalized intensity is greater than zero. The larger span of the vertical angle compared to the horizontal angle reflects the asymmetry between vertical far field component 112 and horizontal far field component 110.

FIG. 2B shows graph 202, which displays the data of heat map 200 in graphical format in accordance with an embodiment of the present disclosure. As shown by graph 202, the horizontal angle of horizontal far field component 110 spans from about −40 degrees to about 40 degrees. However, most of the emitted light is concentrated between about −15 degrees to about 15 degrees. The vertical angle of vertical far field component 112 spans from about −80 degrees to about 80 degrees, with most of the emitted light concentrated between about −25 degrees to about 25 degrees. Graph 202 therefore further shows the asymmetry between vertical far field component 112 and horizontal far field component 110.

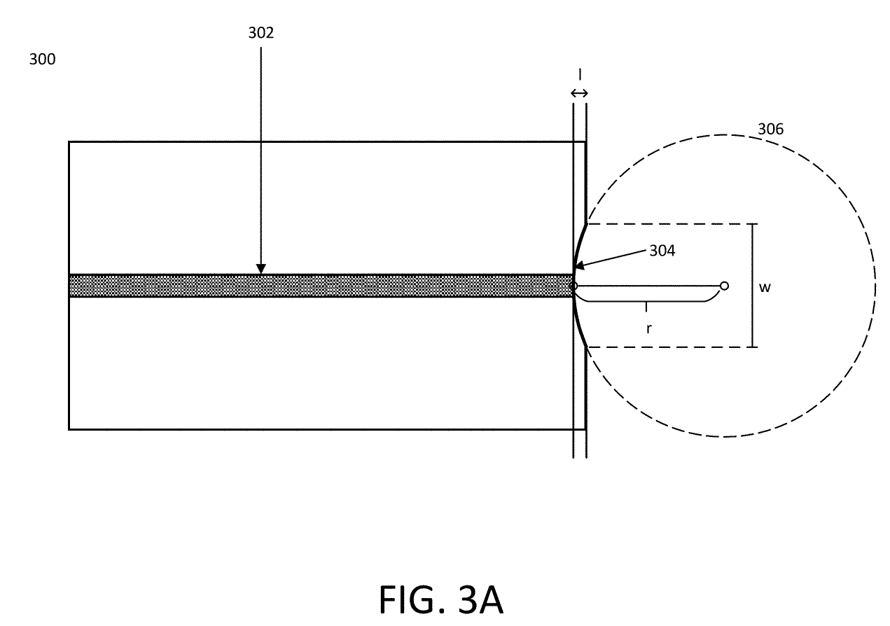

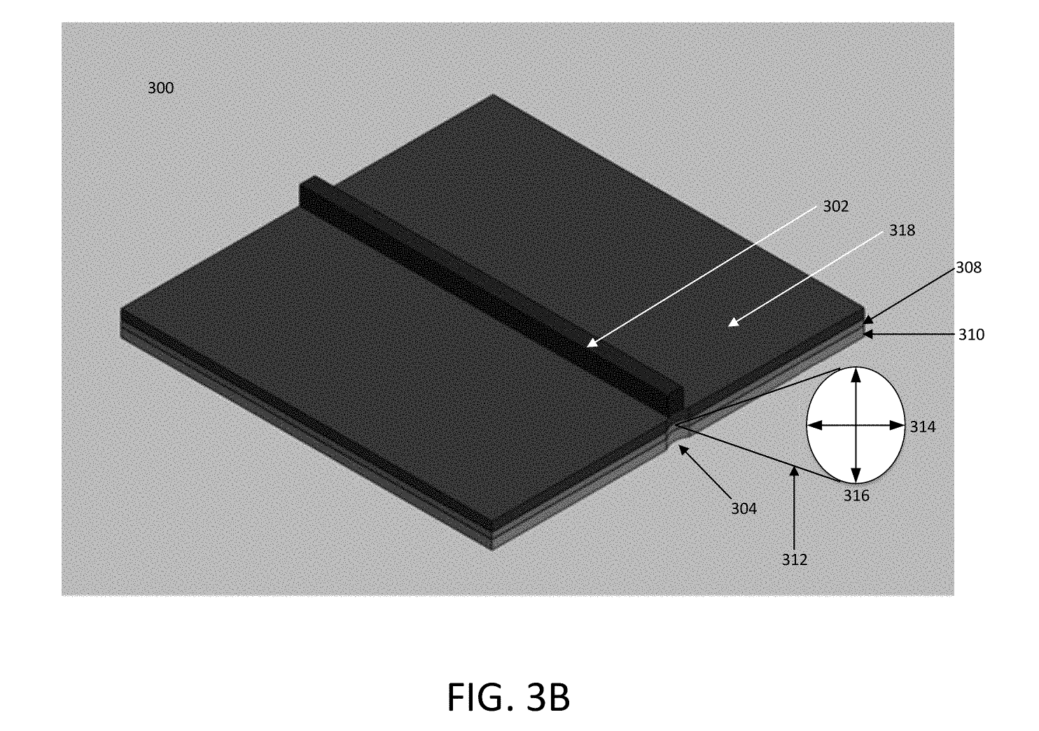

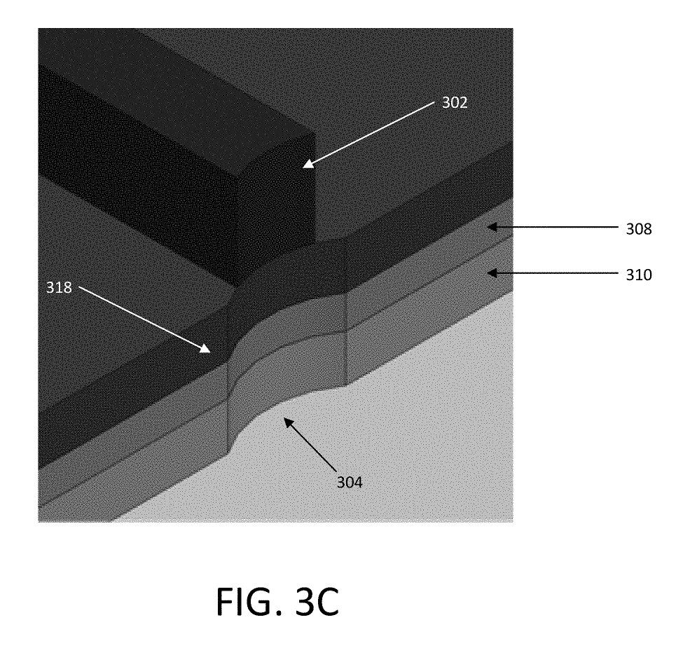

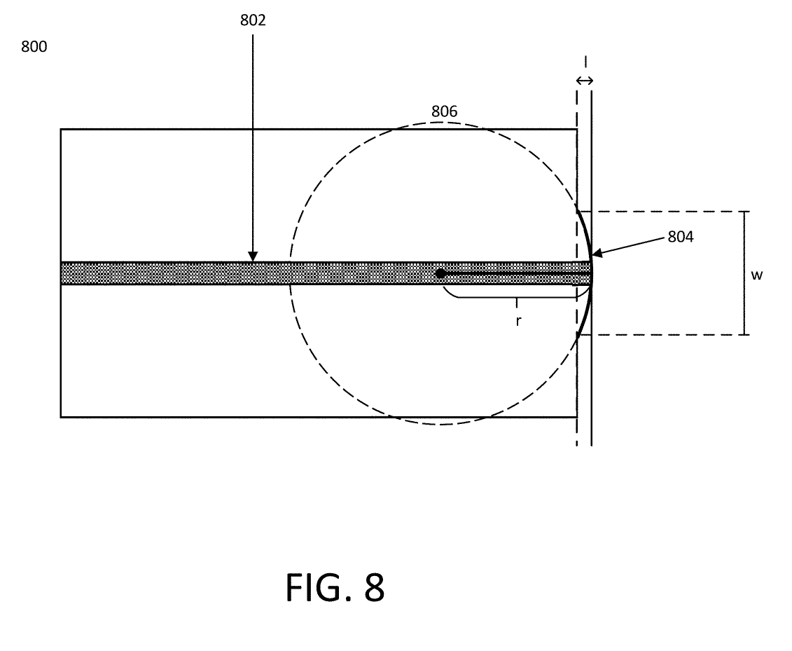

FIG. 3A shows a top view of a semiconductor laser 300 in accordance with an embodiment of the present disclosure. Semiconductor laser 300 may be a ridge diode laser that includes ridge 302. Semiconductor laser 300 may also include a waveguide and substrate (not shown in FIG. 3A). Semiconductor laser 300 may include a concave curved facet 304. Concave curved facet 304 may be etched away from semiconductor laser 300 using chemically assisted ion beam etching, for example. Other kinds of etching methods, such as reactive-ion etching—inductively coupled plasma (RIE-ICP) etching or wet etching may also or alternatively be used. Concave curved facet 304 may have a concave shape relative to the edge of semiconductor laser 300 including the facet, as shown from the top view in FIG. 3A. Alternatively, a differently shaped facet may be provided. For example, the curved facet may be convex curved facet (as will be discussed in relation to FIG. 8), or may be a differently shaped curve. For example, stair-like shaped structures may be used.

Concave curved facet 304 may extend from a first location of semiconductor laser 300 where concave curved facet 304 begins to a second location of semiconductor laser 300 where concave curved facet 304 ends. The distance between the first and second locations is the width of the curved facet, and is represented by “w” in FIG. 3A. The value “l” of FIG. 3A represents the distance from the edge of semiconductor laser 300 to the minimum depth of concave curved facet 304. The curve of concave curved facet 304 may be extended into a circle 306 that includes a radius “r.” Circle 306 is not a component of semiconductor laser 300, but instead symbolizes the shape that would be created if the curvature of concave curved facet 304 formed part of a circle. The values “w,” “r,” and “l” satisfy the equation (w/2)²+(r−l)²=r².

By adjusting the radius “r” of circle 306, the curvature of concave curved facet 304 may be modified. For example, by increasing the radius “r” and keeping “l” constant, the curvature of concave curved facet 304 may be reduced. In contrast, for example, by decreasing the radius “r” and keeping “l” constant, the curvature of concave curved facet 304 may be increased. Adjusting the radius “r” may also modify the horizontal far field angle of light emitted from semiconductor laser 300. By decreasing radius “r” and keeping “l” constant, the horizontal far filed angle may increase.

FIG. 3B shows three-dimensional cross section view of semiconductor laser 300 in accordance with an embodiment of the present disclosure. As shown by FIG. 3B, semiconductor laser 300 includes a ridge 302, waveguide 308, and substrate 310. FIG. 3B also shows another viewpoint of concave curved facet 304. A spacer layer 318 may positioned between ridge 302 and waveguide 308. Spacer layer 318 may be made from the same material(s) as ridge 302. Alternatively, spacer layer 318 may be part of ridge 302, and may be a residual layer that together with ridge 302 is a single structure.

As shown in FIG. 3B, light 312 is emitted from waveguide 308 at a facet of semiconductor laser 300. Light 312 has a horizontal far field component 314 and a vertical far field component 316. Like components 110 and 112 of light 108 discussed above, horizontal far field component 314 and a vertical far field component 316 may diverge in different directions at different angles. However, concave curved facet 304 may reduce this asymmetry by correcting the divergence without additional optical elements. Therefore, the size of vertical far field component 316 may be closer to the size of horizontal far field component 314, and light 312 emitted by semiconductor laser 300 may be more symmetric compared to the light 108 emitted by semiconductor 100. Indeed, light 312 may have a more symmetrical far field pattern compared to light 108.

Upon coupling light 312 to a transmission medium, such as an optical fiber, the improved far field pattern may reduce the amount of astigmatism that is present compared to coupling of light 108. This reduction is because the virtual focal points of horizontal far field component 314 and vertical far field component 316 may be at closer locations. Compared to coupling of light 108, the reduction of astigmatism may increase coupling efficiency to the transmission medium, and coupling loss may be decreased. Complex aspherical optical elements, such as lenses, may not be required in order to couple light 308 to a transmission medium. Moreover, the cost of fabricating and using semiconductor laser 300 may be less than the cost of fabricating and using semiconductor laser 100. In addition, the facet curvature may reduce mode reflectivity, which may be desirable in semiconductor optical amplifier applications.

FIG. 3C shows a close-up view of concave curved facet 304 in accordance with an embodiment of the present disclosure, and shows ridge 302, waveguide 308, and substrate 310. Each layer of semiconductor laser 300 may be etched to form concave curved facet 304. However, alternatively, only waveguide 308 alone may be etched to be curved, or waveguide 308 along with one or more of substrate 310 and ridge 302 may be etched to be curved.

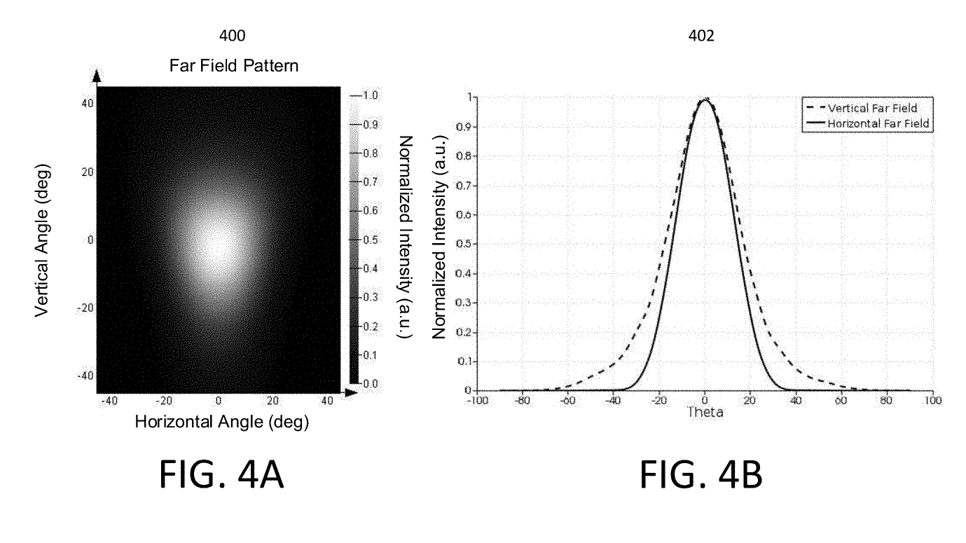

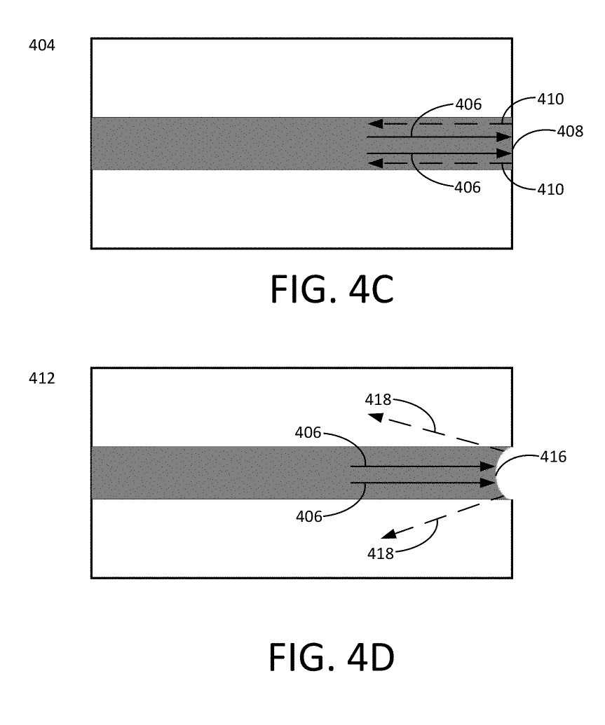

FIG. 4A shows a simulated heat map 400 of light 312 in accordance with an embodiment of the present disclosure. Heat map 400 indicates the vertical angle of the vertical far field component 316 on its left-hand y-axis. The horizontal angle of the horizontal far field component 314 is included on the x-axis of heat map 400. The normalized intensity of light 312 in arbitrary units (a.u.) is included on the right-hand y-axis of heat map 400.

As shown by heat map 400, the vertical angle of the vertical far field component 316 spans a larger range of angles where normalized intensity is greater than zero compared to the horizontal angle of the horizontal far field component 314. However, compared to heat map 200 in FIG. 2A, for example, the span for the horizontal angle may be about the same or larger, while the span for the vertical angle may be not as large or the same. Therefore, heat map 400 shows that the concave curved facet 304 of semiconductor laser 300 may increase the horizontal far-field component of emitted light and/or reduce the vertical far field component of emitted light. Since the horizontal angle may be slightly larger, heat map 400 also shows that the horizontal far field component of emitted light is increased. The increase of the horizontal far field component and/or decrease of the vertical far field component may reduce the asymmetry of the vertical and horizontal far field components because the spans of angles are more closely matched. Moreover, concave curved facet 304 may improve anti-reflection properties of semiconductor laser 300.

FIG. 4B shows graph 402, which displays the data of heat map 400 in graphical format in accordance with an embodiment of the present disclosure. As shown by graph 402, the horizontal angle of the horizontal far field component 314 spans from about −40 degrees to about 40 degrees. However, most of the emitted light is concentrated between about −20 degrees to about 20 degrees, showing an increase compared the graph 202 in FIG. 2B. For example, the vertical angle of the vertical far field component 316 may be considered to span from about −60 degrees to about 60 degrees, or may be considered to span from about −80 degrees to about 80 degrees. Thus, the vertical angle span for semiconductor 300 may be therefore be considered as reduced or essentially unchanged from the span of vertical angles for semiconductor laser 100, shown in FIG. 2B. The results of graph 402 and heat map 400 therefore may show a reduction of asymmetry in the vertical and/or horizontal far field components of light emitted by semiconductor laser 300 compared to the light emitted by semiconductor laser 100. The results may further show that the concave curved facet 304 increases the full width half maximum of the horizontal far field component of light emitted from waveguide 308.

FIGS. 4C and 4D show an example of how anti-reflection properties may be improved depending on laser facet. As shown in FIG. 4C, a semiconductor laser 404 is shown. Semiconductor laser 404 may be semiconductor laser 100 shown in FIGS. 1A-1C. Light 406 travels through semiconductor laser 404 and hits facet 408, which is a non-curved facet. Reflected light 410 results, which may travel in a direction parallel to light 406. Because reflected light 410 may be parallel to light 406, there may be a high mode reflectivity in laser 404 and efficiency of light exiting laser 404 may be reduced.

FIG. 4D shows a semiconductor laser 412 is shown. Semiconductor laser 412 may be semiconductor laser 300 shown in FIGS. 3A-3C. Light 406 travels through semiconductor laser 404 and hits concave curved facet 416. Reflected light 418 results, which may travel in a direction that is not parallel to light 406. Because reflected light 418 may not be parallel to light 406, there may be a reduction in mode reflectivity in laser 412 and efficiency of light exiting laser 412 may be increased.

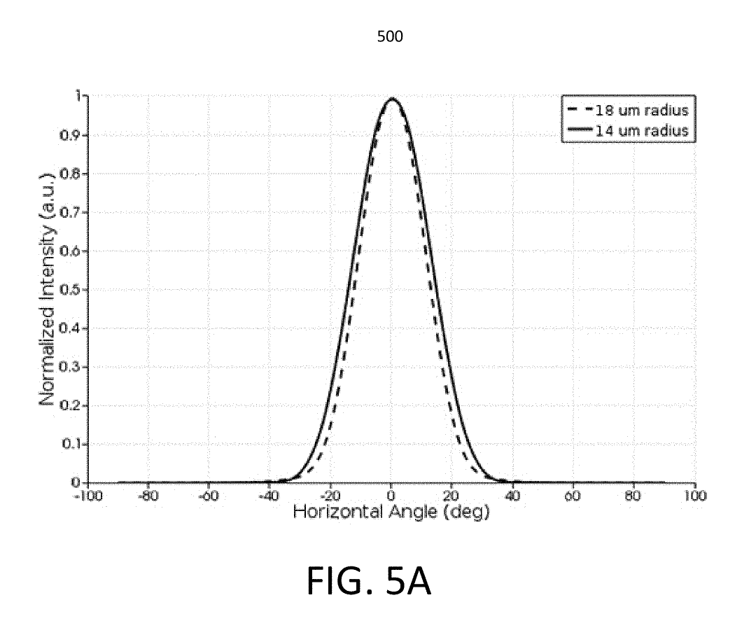

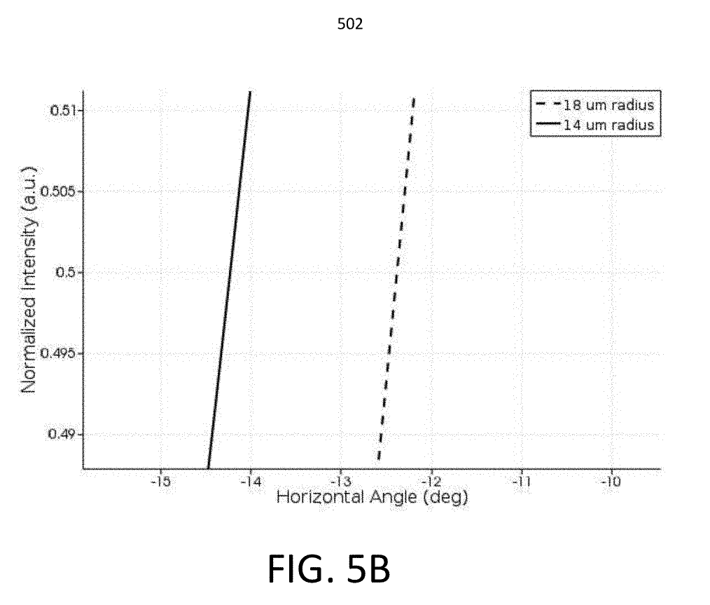

FIG. 5A shows graph 500, which displays different spans of the horizontal angle of the horizontal far field component of light emitted from waveguide 308 via concave curved facet 304 when the radius “r” is changed and “l” is kept constant in accordance with an embodiment of the present disclosure. As shown by the plot for a 14 um radius, the angular span was from about −50 degrees to about 50 degrees. For the 18 um radius, the angular span was from about from −40 degrees to about 40 degrees. Therefore, curvature of concave curved facet 304 can be modified to adjust the horizontal angle of the horizontal far field component of light emitted from waveguide 308.

FIG. 5B shows a zoomed-in portion 502 of the graph 500 shown in FIG. 5A. As shown by FIG. 5B, the 18 um radius concave curved facet results in a smaller horizontal angle span relative to the 14 um radius concave curved facet.

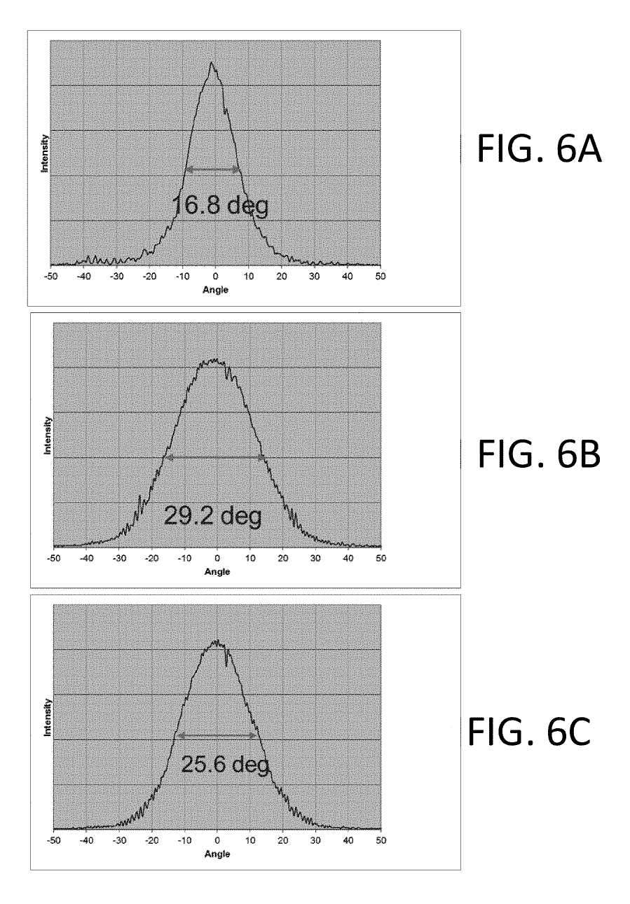

FIGS. 6A-6C show experimental results from testing a reference semiconductor laser (e.g., semiconductor laser 100) and semiconductor lasers with varying edge facet curvatures (e.g., semiconductor laser 300) in accordance with an embodiment of the present disclosure. The resulting plots show horizontal far field plots for difference lasers, and how wide output laser beams diverge when they exit different lasers. The plots also show how wide the angle of usable light intensity is within each plot's half intensity. The x-axis is the angle in the horizontal direction. The y-axis is the power intensity in arbitrary units (a.u.).

FIG. 6A shows horizontal angles of the horizontal far field component of emitted light emitted by a reference semiconductor laser without facet curvature. This laser showed a full-width half maximum of horizontal far field of 16.8 degrees.

FIG. 6B shows horizontal angles of the horizontal far field component of emitted light emitted by a 14 um concave facet curvature semiconductor laser. This laser showed a full-width half maximum of horizontal far field of 29.2 degrees.

FIG. 6C shows horizontal angles of the horizontal far field component of emitted light emitted by an 18 um concave facet curvature semiconductor laser. This laser showed a full-width half maximum of horizontal far field of 25.6 degrees.

Therefore, the results shown in FIGS. 6A-6C show that curved facet semiconductor lasers provide wider horizontal far field laser output compared to the reference semiconductor laser without facet curvature. The curved facet semiconductor lasers therefore show better performance compared to the reference semiconductor laser without facet curvature. The experimental results also show that the horizontal far field changes as the curvature of concave curved facet 304 changes, and that far field size can be tuned based on changing curvature radius “r.”

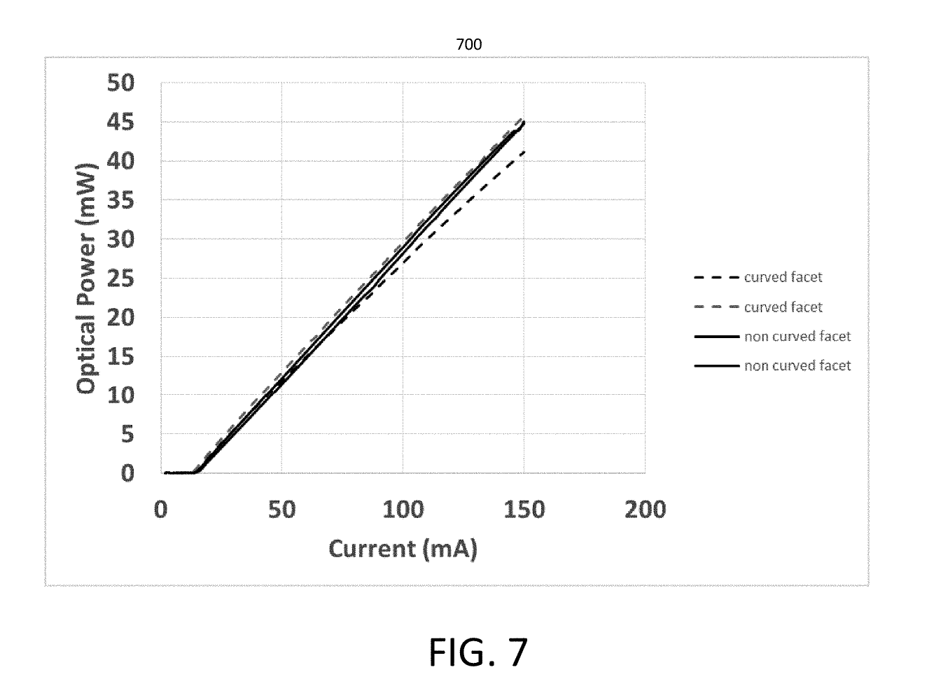

FIG. 7 shows a graph 700 which reflects the output optical power in milliwatts (mW) of semiconductor lasers versus current in milliamps (mA) in accordance with an embodiment of the present disclosure. Curved facet semiconductor laser performance, shown by dashed lines, is compared to non-curved facet semiconductor performance, shown by solid lines. As shown by graph 700, the output light power of semiconductor lasers with a curved facet (e.g., semiconductor laser 300) is not significantly different to semiconductor lasers without a curved facet (e.g., semiconductor laser 100) and is within a tolerance range. Therefore, there is no significant effect of facet curvature on semiconductor laser performance, such as semiconductor laser output optical power performance, for example.

FIG. 8 shows a top view of a semiconductor laser 800 in accordance with an embodiment of the present disclosure. Semiconductor laser 800 may be a ridge diode laser that includes ridge 802. Semiconductor laser 800 may also include a waveguide and substrate (not shown in FIG. 8). Ridge 802 may be the same as ridge 302, which is described above. The waveguide and substrate of semiconductor laser 800 may be, for example, the same as waveguide 308 and substrate 310 as described above.

Semiconductor laser 800 may include a convex curved facet 804. Convex curved facet 804 may be formed by etching semiconductor laser 800 using chemically assisted ion beam etching, for example. Convex curved facet 804 may have a convex shape relative to the edge of semiconductor laser 800 including the facet, as shown from the top view in FIG. 8. Alternatively, the curved facet may be a differently shaped curve.

Convex curved facet 804 may extend from a first location of semiconductor laser 300 where convex curved facet 804 begins to a second location of semiconductor laser 300 where convex curved facet 804 ends. The distance between the first and second locations is the width of the curved facet, and is represented by “w” in FIG. 8. The value “l” of FIG. 8 represents the distance from the minimum convex depth of curved facet 804 to the edge of semiconductor laser 800 that has been etched. The curve of convex curved facet 804 may be extended into a circle 806 that includes a radius “r.” Circle 806 is not a component of semiconductor laser 800, but instead symbolizes the shape that would be created if the curvature of convex curved facet 804 formed part of a circle. The values “w,” “r,” and “l” satisfy the equation (w/2)²+(r−l)²=r².

By adjusting the radius “r” of circle 806, the curvature of convex curved facet 804 may be modified. For example, by increasing the radius “r” and keeping “l” constant, the curvature of convex curved facet 804 may be reduced. In contrast, for example, by decreasing the radius “r” and keeping “l” constant, the curvature of convex curved facet 804 may be increased. Adjusting the radius “r” may also modify the horizontal far field angle of light emitted from semiconductor laser 800.

Referring back to FIG. 4C, in another embodiment, optically transparent material may be deposited or otherwise placed in front of facet 408 of laser 404 in FIG. 4C to modify how light exits laser 404 and improve the functioning of laser 404. For example, the optically transparent material may be high index optically transparent material. The material may be shaped or etched, for example, in the same form as facet 408 as shown in FIG. 4C (e.g., such that it forms a non-curved facet similar to facet 408). In another embodiment, the material may be shaped or etched, for example, in the same form as facet 416 as shown in FIG. 4D (e.g., such that it forms a concave curved facet similar to facet 416). In another embodiment, the material may be shaped or etched, for example, in the same form facet 804 as shown in FIG. 8 (e.g., such that it forms a convex curved facet similar to facet 804).

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of at least one particular implementation in at least one particular environment for at least one particular purpose, those of ordinary skill in the art will recognize that its usefulness is not limited thereto and that the present disclosure may be beneficially implemented in any number of environments for any number of purposes.

1. A semiconductor laser, comprising:
a waveguide;
wherein the waveguide includes a facet formed at an edge of the semiconductor laser, and the facet has a curvature.

2. The semiconductor laser of claim 1, wherein the facet curvature is based on a width of the facet or a depth of the facet.

3. The semiconductor laser of claim 2, wherein the depth of the facet is measured from the edge of the semiconductor laser to a minimum depth of the facet.

4. The semiconductor laser of claim 3, wherein the minimum depth of the facet is located in a central region of the facet.

5. The semiconductor laser of claim 1, wherein the facet curvature is based on a radius.

6. The semiconductor laser of claim 1, wherein the facet is configured to emit light, and the facet curvature causes the emitted light to have a reduced amount of far field asymmetry relative to light emitted without the facet curvature.

7. The semiconductor laser of claim 1, wherein the facet curvature is formed by chemically assisted ion beam etching.

8. The semiconductor laser of claim 1, wherein the facet curvature is concave relative to the edge of the semiconductor laser.

9. The semiconductor laser of claim 1, wherein the facet curvature is convex relative to the edge of the semiconductor laser.

10. The semiconductor laser of claim 1, wherein the facet curvature satisfies the following equation:
(w/2)²+(r−l)²=r²
where w is a width of the facet, r is a radius, and l is a depth of the facet.

11. A method of semiconductor laser fabrication, comprising:
etching a facet in a waveguide at an edge of a semiconductor laser including the waveguide, wherein the facet has a curvature.

12. The method of claim 11, wherein the facet curvature is based on a width of the facet or a depth of the facet.

13. The method of claim 11, wherein the facet curvature is based on a radius.

14. The method of claim 11, wherein the facet curvature is formed by chemically assisted ion beam etching.

15. The method of claim 11, wherein the facet curvature is concave relative to the edge of the semiconductor laser.

16. The method of claim 11, wherein the facet curvature is convex relative to the edge of the semiconductor laser.

17. A semiconductor laser, comprising:
a waveguide; and
a substrate attached to the waveguide;
wherein the waveguide and the substrate include a facet formed at an edge of the semiconductor laser, and the facet has a curvature.

18. The semiconductor laser of claim 17, wherein the facet curvature is concave relative to the edge of the semiconductor laser.

19. The semiconductor laser of claim 17, wherein the facet curvature is convex relative to the edge of the semiconductor laser.

20. The semiconductor laser of claim 17, wherein the facet curvature satisfies the following equation:
(w/2)²+(r−l)²=r²
where w is a width of the facet, r is a radius, and l is a depth of the facet.
